(19) United States
(12) Patent Application Publication
(10) Pub. No.: US 2018/0308836 A1
(43) Pub. Date: Oct. 25, 2018

(54) ELECTROSTATIC DISCHARGE PROTECTION DEVICE AND METHOD FOR ELECTROSTATIC DISCHARGE

(71) Applicant: MACRONIX International Co., Ltd., Hsinchu (TW)

(72) Inventors: Min-Hsin Wu, Hsinchu (TW); Hsin-Liang Chen, Hsinchu (TW)

(73) Assignee: MACRONIX International Co., Ltd., Hsinchu (TW)

(21) Appl. No.: 15/495,141

(22) Filed: Apr. 24, 2017

(51) Int. Cl. H01L 27/02; H01L 29/06; H02H 3/20

(52) U.S. Cl. CPC H01L 27/0262; H02H 3/20; H01L 29/0649

(57) ABSTRACT

An electrical static discharge (ESD) protection device and a method for ESD are provided. The ESD protection device includes first and second wells and fourth through sixth doped regions. The first and second wells are located in a substrate. The first well has first through third doped regions, so as to form a first transistor. The second well is located aside the first well. The fourth through sixth doped regions are located in the second well. The fourth doped region is contacted with the third doped region. A conductive type of the fourth doped region is the same with a conductive type of the third doped region. The fifth doped region, the second well and the substrate forms a second transistor, of which a conductive type is complementary to a conductive type of the first transistor. The fifth doped region is located between the fourth and sixth doped regions.

### BACKGROUND OF THE INVENTION

### Field of the Invention

The invention relates to an electrostatic discharge protection device, and particularly relates to a silicon controlled rectifier.

### Description of Related Art

Electrostatic discharge (ESD) protection device is widely applied in electronic devices for preventing damage of the electronic devices due to reception of an abnormal high voltage. Silicon controlled rectifier (SCR) is a commonly used ESD protection device and has advantages of a small area and high voltage tolerance, etc.

However, a general SCR has disadvantages of a large trigger voltage and a small holding voltage. Therefore, although the abnormal high voltage does not exceed the trigger voltage of the SCR, it may still cause damage of electronic device. Moreover, if the holding voltage of the SCR is smaller than an operation voltage of the electronic device, a latch-up effect is probably caused when the SCR is turned on. To be specific, after the SCR is triggered, it cannot return back to a normal operation state and generates a transient large current. Therefore, it causes damage of the electronic device.

### SUMMARY OF THE INVENTION

The invention is directed to an electrostatic discharge protection device and a method for electrostatic discharge, which are adapted to produce a latch-up effect.

The invention provides an electrostatic discharge protection device including a first well, a second well, a fourth doped region, a fifth doped region and a sixth doped region. The first well is located in a substrate, and has a first doped region, a second doped region and a third doped region to form a first transistor. The second well is located in the substrate at one side of the first well. The fourth doped region, the fifth doped region and the sixth doped region are located in the second well. The fourth doped region is contacted with the third doped region, and a conductive type of the fourth doped region is the same with a conductive type of the third doped region. The fifth doped region, the second well and the substrate form a second transistor. A conductive type of the second transistor is complementary to a conductive type of the first transistor. The fifth doped region is located between the fourth doped region and the sixth doped region.

In an embodiment of the invention, the substrate, the first well, the first doped region and the fifth doped region have a first conductive type. The second well, the second doped region, the third doped region, the fourth doped region and the sixth doped region have a second conductive type.

In an embodiment of the invention, the second doped region is located between the first doped region and the third doped region.

In an embodiment of the invention, a ratio between a width of the third doped region measured from one side opposite to the fourth doped region to another side contacting the fourth doped region and a width of the fourth doped region measured from one side contacting the third doped region to another side opposite to the third doped region is within a range of 1 to 4.

In an embodiment of the invention, the electrostatic discharge protection device further includes a first stack structure. The first stack structure is located on the first well between the second doped region and the third doped region. The first stack structure includes a first insulation layer and a first conductive layer sequentially stacked on the substrate.

In an embodiment of the invention, the electrostatic discharge protection device further includes a first isolation structure and a second isolation structure. The first isolation structure is located between the first doped region and the second doped region. The first doped region is located between the first isolation structure and the second isolation structure.

In an embodiment of the invention, the first doped region, the second doped region and the first conductive layer are electrically connected to a cathode. The third doped region, the fourth doped region, the fifth doped region and the sixth doped region are electrically connected to an anode.

In an embodiment of the invention, a top view pattern of the first well surrounds a top view pattern of the second well.

In an embodiment of the invention, the electrostatic discharge protection device further includes a seventh doped region, an eighth doped region and a ninth doped region. The first doped region, the second doped region and the third doped region are located at a first side of the second well, and the seventh doped region, the eighth doped region and the ninth doped region are located at a second side of the second well. The first side and the second side are opposite to each other. The seventh doped region, the eighth doped region and the ninth doped region form another transistor, and a conductive type thereof is the same with the conductive type of the first transistor.

In an embodiment of the invention, the ninth doped region has the first conductive type, and the seventh doped region and the eighth doped region have the second conductive type.

In an embodiment of the invention, a ratio between a width of the sixth doped region measured from one side opposite to the seventh doped region to another side contacting the seventh doped region and a width of the seventh doped region measured from one side contacting the sixth doped region to another side opposite to the sixth doped region is within a range of 0.25 to 1.

In an embodiment of the invention, the electrostatic discharge protection device further includes a third isolation structure and a fourth isolation structure. The third isolation structure is located between the eighth doped region and the ninth doped region. The ninth doped region is located between the third isolation structure and the fourth isolation structure.

In an embodiment of the invention, the electrostatic discharge protection device further includes a second stack structure. The second stack structure is located on the first well between the seventh doped region and the eighth doped region, and the second stack structure includes a second insulation layer and a second conductive layer sequentially stacked on the substrate.

In an embodiment of the invention, the third doped region, the fourth doped region, the fifth doped region, the sixth doped region and the seventh doped region are electrically connected to the anode. The first doped region, the second doped region, the first conductive layer, the eighth doped region, the second conductive layer and the ninth doped region are electrically connected to the cathode.

The invention provides a method for electrostatic discharge including following steps. The aforementioned electrostatic discharge protection device is provided. The third doped region, the fourth doped region, the fifth doped region and the sixth doped region are electrically connected. The first doped region and the second doped region are electrically connected. The third doped region, the fourth doped region, the fifth doped region and the sixth doped region receive an electrostatic voltage. The first doped region and the second doped region are connected to a ground electrode. The first transistor is turned on within a first time interval according to the electrostatic voltage. The second transistor is turned on within a second time interval according to the electrostatic voltage, such that the first transistor and the second transistor discharge electrostatic charges.

In an embodiment of the invention, a start point of the first time interval is different to a start point of the second time interval.

In an embodiment of the invention, the start point of the first time interval is earlier than the start point of the second time interval.

According to the above description, by setting the third doped region and the fourth doped region contacted with each other and having the same conductive type at two sides of the interface of the first well and the third well, the first transistor and the second transistor can be turned on at different time points. In this way, a silicon controlled rectifier (SCR) of the electrostatic discharge protection device may have double snap-back characteristics. Therefore, the SCR has a lower trigger voltage, so as to mitigate the damage on the electronic device caused by abnormal high voltage. Moreover, the SCR may also have a higher holding voltage, so as to avoid a situation that an operation voltage of the electronic device electrically coupled to the electrostatic discharge protection device exceeds the holding voltage to trigger the latch-up effect.

In order to make the aforementioned and other features and advantages of the invention comprehensible, several exemplary embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1A is a cross-sectional view of an electrostatic discharge (ESD) protection device according to an embodiment of the invention.

FIG. 1B is a top view of FIG. 1A.

FIG. 1C is a current-voltage diagram of a silicon controlled rectifier (SCR) of the ESD protection device according to an embodiment of the invention.

FIG. 1D is a flowchart illustrating a method for ESD according to an embodiment of the invention.

FIG. 2A is a cross-sectional view of an ESD protection device according to another embodiment of the invention.

FIG. 2B is a top view of FIG. 2A.

### DESCRIPTION OF EMBODIMENTS

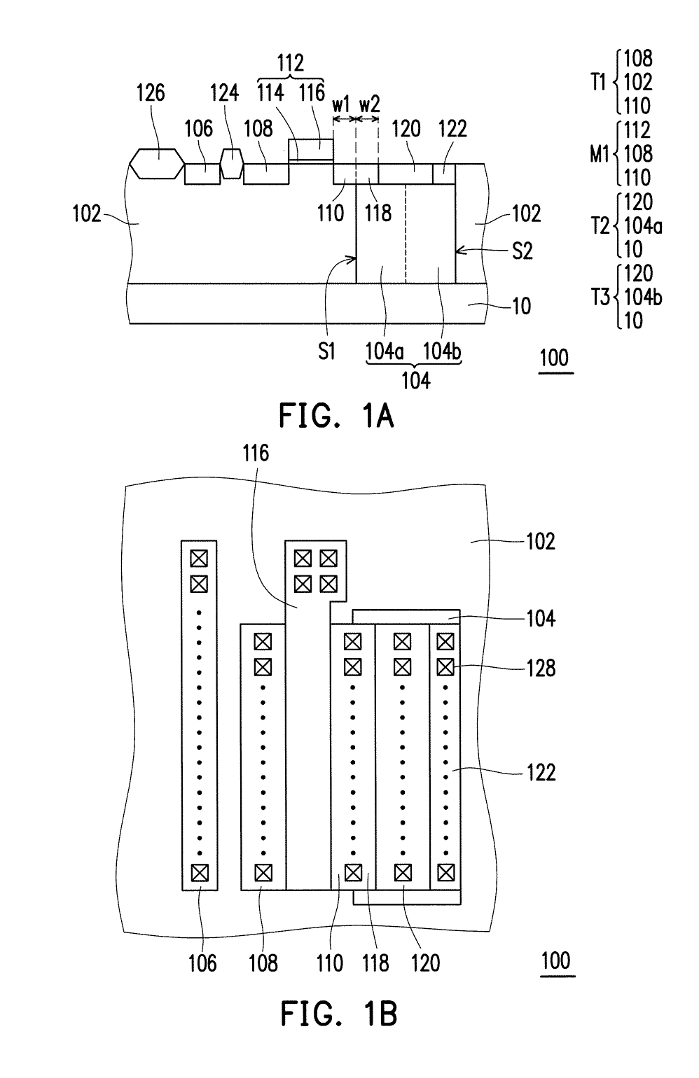

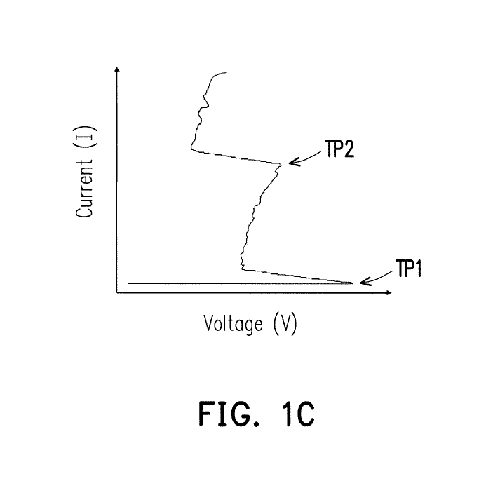

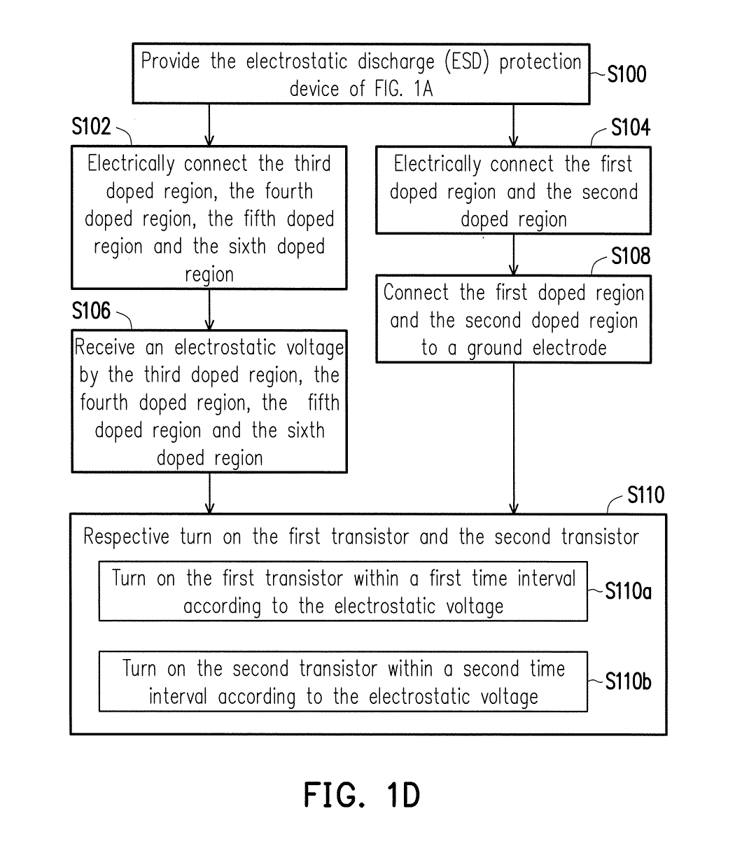

FIG. 1 A is a cross-sectional view of an electrostatic discharge (ESD) protection device according to an embodiment of the invention. FIG. 1B is a top view of FIG. 1A. FIG. 1C is a current-voltage diagram of a silicon controlled rectifier (SCR) of the ESD protection device according to an embodiment of the invention.

The ESD protection device 100 of the present embodiment includes a first well 102 and a second well 104. The first well 102 and the second well 104 are located in a substrate 10. In some embodiments, the substrate 10 includes a semiconductor substrate or a silicon on insulator (SOI) substrate, and the semiconductor substrate may have an epitaxial layer thereon. For example, a material of the semiconductor substrate and the epitaxial layer may include silicon, germanium, gallium arsenide, silicon carbide, indium arsenide or indium phosphide, etc. The first well 102 can be doped to have a first conductive type, and the second well 104 can be doped to have a second conductive type. In some embodiments, the first conductive type can be a P-type, and the second conductive type can be an N-type. In other embodiments, the first conductive type can also be the N-type, and now the second conductive type can be the P-type. For example, N-type dopant includes phosphorus or arsenic. Moreover, the P-type dopant may include boron. In some embodiments, in view of the top view (as shown in FIG. 1B), the first well 102 may surround the second well 104. In other words, in view of the cross-sectional view (as shown in FIG. 1A), the first well 102 can be located at a first side S1 and a second side S2 of the second well 104 that are opposite to each other. In other embodiments, the first well 102 can be located at the first side S1 of the second well 104.

The first well 102 has a first doped region 106, a second doped region 108 and a third doped region 110. The first doped region 106 may have the first conductive type, and the second doped region 108 and the third doped region 110 may have the second conductive type. The second doped region 108 can be located between the first doped region 106 and the third doped region 110. Moreover, the second doped region 108, the first well 102 and the third doped region 110 may form a first transistor T1. The first transistor T1 can be a bipolar junction transistor (BJT). Particularly, the second doped region 108, the first well 102 and the third doped region 110 may respectively serve as an emitter, a base and a collector of the BJT.

The ESD protection device 100 may further include a first stack structure 112. The first stack structure 112 can be located between the second doped region 108 and the third doped region 110. The first stack structure 112 may include a first insulation layer 114 and a first conductive layer 116 sequentially stacked on the substrate 10. In some embodiments, the first stack structure 112, the second doped region 108 and the third doped region 110 may form a metal-oxide-semiconductor (MOS) transistor M1. Particularly, the first conductive layer 116 and the first insulation layer 114 of the first stack structure 112 may respectively serve as a gate and a gate dielectric layer of the MOS transistor M1. A material of the first conductive layer 116 may include polysilicon or a metal material. For example, the metal material may include tungsten or aluminum. A material of the first insulation layer 114 may include silicon oxide or other high dielectric constant material (for example, the dielectric constant is greater than 4). For example, the high dielectric constant material may include hafnium silicate, zirconium silicate, hafnium dioxide or zirconium dioxide. Moreover, the second doped region 108 and the third doped region 110 may serve as a drain/source of the MOS transistor M1.

The ESD protection device 100 may further include a fourth doped region 118, a fifth doped region 120 and a sixth doped region 122. The fifth doped region 120 has the first conductive type, and the fourth doped region 118 and the sixth doped region 122 has the second conductive type. The fourth doped region 118, the fifth doped region 120 and the sixth doped region 122 are located in the second well 104. The fifth doped region 120 is located between the fourth doped region 118 and the sixth doped region 122. The fourth doped region 118 is contacted with the third doped region 110, and a conductive type of the fourth doped region 118 is the same with that of the third doped region 110. In some embodiments, the third doped region 110 and the fourth doped region 118 can be two portions of a same doped region that are contacted with each other. Particularly, the third doped region 110 is a portion of the doped region in the first well 102, and the fourth doped region 118 is another portion of the doped region in the second well 104. Moreover, a ratio (W1/W2) between a width W1 of the third doped region 110 measured from one side opposite to the fourth doped region 118 to another side contacting the fourth doped region 118 and a width W2 of the fourth doped region 118 measured from one side contacting the third doped region 110 to another side opposite to the third doped region 110 is within a range of 1 to 4. The aforementioned range can be determined according to an operation voltage and process parameters of the ESD protection device 100, which is not limited by the invention.

The second well 104 may be divided into a first portion 104a facing the first stack structure 112 and a second portion 104b opposite to the first stack structure 112. The fifth doped region 120, the first portion 104a of the second well 104 and the substrate 10 may form a second transistor T2. The second transistor T2 can also be a BJT, and the conductive type of the first transistor T1 and a conductive type of the second transistor T2 are complementary. Particularly, the fifth doped region 120, the first portion 104a of the second well 104 and the substrate 10 can be respectively an emitter, a base and a collector of the BJT. Similarly, the fifth doped region 120, the second portion 104b of the second well 104 and the substrate 10 may form a transistor T3. The third transistor T3 can also be a BJT, and the conductive type of the third transistor T3 and the conductive type of the second transistor T2 are the same. Particularly, the fifth doped region 120, the second portion 104b of the second well 104 and the substrate 10 can be respectively an emitter, a base and a collector of the BJT. In some embodiments, the first transistor T1, the second transistor T2 and the third transistor T3 may construct a silicon controlled rectifier (SCR), where the third transistor T3 and the second transistor T2 are connected in parallel. In other embodiments, the SCR may include the first transistor T1 and the second transistor T2.

The ESD protection device 100 may further include a first isolation structure 124 and a second isolation structure 126. The first isolation structure 124 is located between the first doped region 106 and the second doped region 108, and the first doped region 106 is located between the first isolation structure 124 and the second isolation structure 126. For simplicity's sake, the first isolation structure 124 and the second isolation structure 126 are omitted in FIG. 1B. In some embodiments, the first isolation structure 124 and the second isolation structure 126 can be a field oxide layer (FOX) or a local oxidation of silicon (LOCOS) structure, and can be disposed on the substrate 10. In other embodiments, the first isolation structure 124 and the second isolation structure 126 can also be a shallow trench isolation (STI) structure, and is disposed in the substrate 10.

In some embodiments, the first doped region 106, the second doped region 108 and the first conductive layer 116 can be electrically connected to a cathode through contacts 128. The cathode can be a ground electrode. The third doped region 110, the fourth doped region 118, the fifth doped region 120 and the sixth doped region 122 can be electrically connected to an anode through the contacts 128. The anode can be used for receiving an abnormal high voltage. For example, the abnormal high voltage includes noise or an electrostatic voltage. Moreover, the ESD protection device 100 can be electrically coupled to an electronic device. When the electronic device receives the abnormal high voltage during the operation thereof, the SCR of the ESD protection device 100 is turned on to discharge charges.

Particularly, the first transistor T1 and the second transistor T2 of the SCR of the present embodiment can be turned on at different time points. In some embodiments, the first transistor T1 can be first turned on, and then the second transistor T2 is turned on. In this way, referring to FIG. 1C, the SCR of the present embodiment may have double snap-back characteristics. A first turning point TP1 and a second turning point TP2 of a current-voltage curve respectively represent turning-on of the first transistor T1 and turning-on of the second transistor T2. Moreover, while the second transistor T2 is turned on, the third transistor T3 connected in parallel with the second transistor T2 is also turned on. In other embodiments, the second transistor T2 and the third transistor T3 can be first turned on, and then the first transistor T1 is turned on.

FIG. 1D is a flowchart illustrating a method for ESD according to an embodiment of the invention. The method for ESD of the present embodiment includes following steps.

In step S100, the ESD protection device 100 of FIG. 1A is provided. In step S102, the third doped region 110, the fourth doped region 118, the fifth doped region 120 and the sixth doped region 122 are electrically connected. Particularly, the third doped region 110 the fourth doped region 118 and the fifth doped region 120 can be electrically connected to the anode through the contacts 128.

When the step S102 is executed, a step S104 is also executed to electrically couple the first doped region 106 and the second doped region 108. In the step S104, the first conductive layer 116 of the first stack structure 112 can be further electrically coupled to the first doped region 106 and the second doped region 108. Moreover, the first conductive layer 116, the first doped region 106 and the second doped region 108 can be electrically coupled to the cathode through the contacts 128.

In step S106, the third doped region 110, the fourth doped region 118, the fifth doped region 120 and the sixth doped region 122 receive an electrostatic voltage. While the step S106 is executed, a step S108 is also executed to couple the first doped region 106 and the second doped region 108 to a ground electrode. In the step S108, the first conductive layer 116 of the first stack structure 112 can be further connected to the ground electrode.

In step S110, the first transistor T1 and the second transistor T2 are respectively turned on. The step S110 may include a sub step S110a and a sub step S110b. In the sub step S110a, the first transistor T1 is turned on within a first time interval according to the electrostatic voltage. In the sub step S110b, the second transistor T2 is turned on within a second time interval according to the electrostatic voltage. By turning on the first transistor T1 and the second transistor T2, the electrostatic charges can be discharged. Moreover, since the second transistor T2 and the third transistor T3 are connected in parallel, while the second transistor T2 is turned on, the third transistor T3 is also turned on.

In some embodiments, a start point of the first time interval is different to a start point of the second time interval. Moreover, the first time interval can be partially overlapped with the second time interval. In some embodiments, the start point of the first time interval can be earlier than the start point of the second time interval. In other embodiments, the start point of the second time interval can be earlier than the start point of the first time interval.

According to the above description, by setting the third doped region 110 and the fourth doped region 118 contacted with each other and having the same conductive type at two sides of the interface of the first well 102 and the third well 104, the first transistor T1 and the second transistor T2 can be turned on at different time points. In this way, the SCR of the ESD protection device 100 of the present embodiment may have double snap-back characteristics. Therefore, the SCR of the present embodiment has a lower trigger voltage, so as to mitigate the damage on the electronic device caused by the abnormal high voltage. Moreover, the SCR of the present embodiment may also have a higher holding voltage, so as to avoid a situation that the operation voltage of the electronic device electrically coupled to the electrostatic discharge protection device exceeds the holding voltage to trigger the latch-up effect.

In some embodiments, the SCR including the first transistor T1 to the third transistor T3 and the MOS transistor M1 can be integrated in a same region of the substrate 10, so that it is unnecessary to perform an extra optical mask process to form the ESD protection device in other region of the substrate 10. Therefore, manufacturing cost of the ESD protection device can be decreased, and an area occupied by the ESD protection device is decreased. In addition, by controlling the MOS transistor M1 to maintain a cut off state, current leakage between the second doped region 108 and the third doped region 110 can be decreased. Moreover, by connecting the third transistor T3 and the second transistor T2 in parallel, a current discharge amount of the SCR can be increased. Therefore, the ESD protection device 100 may quickly discharge the charges.

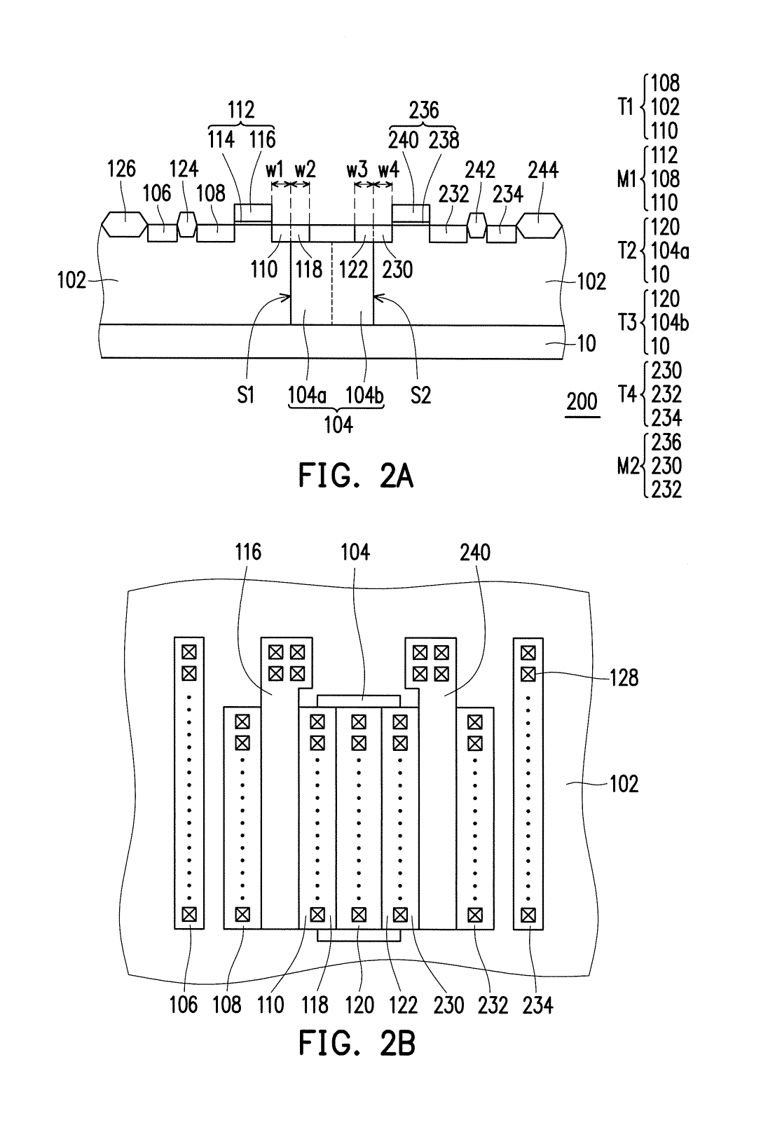

FIG. 2A is a cross-sectional view of an ESD protection device according to another embodiment of the invention. FIG. 2B is a top view of FIG. 2A.

The ESD protection device 200 of the present embodiment is similar to the ESD protection device 100 of FIG. 1A and FIG. 1B, and only differences therebetween are described below, and the same or similar parts are not repeated. Moreover, in the ESD protection device 100 or the ESD protection device 200, the same referential numbers denote the same or similar components.

The ESD protection device 200 further includes a seventh doped region 230, an eighth doped region 232 and a ninth doped region 234. The ninth doped region 234 has the first conductive type, and the seventh doped region 230 and the eighth doped region 232 has the second conductive type. The first doped region 106, the second doped region 108 and the third doped region 110 are located at the first side S1 of the second well 104, and the seventh doped region 230, the eighth doped region 232 and the ninth doped region 234 are located at the second side S2 of the second well 104. The first side S1 and the second side S2 of the second well 104 are opposite to each other. The eighth doped region 232 is located between the seventh doped region 230 and the ninth doped region 234.

The seventh doped region 230 is contacted with the sixth doped region 122, and a conductive type of the seventh doped region 230 is the same with the conductive type of the sixth doped region 122. In some embodiments, the sixth doped region 122 and the seventh doped region 230 can be two portions of a same doped region that are contacted with each other. Particularly, the seventh doped region 230 is a portion of the doped region in the first well 102, and the sixth doped region 122 is another portion of the doped region in the second well 104. Moreover, a ratio (W3/W4) between a width W3 of the sixth doped region 122 measured from one side opposite to the seventh doped region 230 to another side contacting the seventh doped region 230 and a width W4 of the seventh doped region 230 measured from one side contacting the sixth doped region 122 to another side opposite to the sixth doped region 122 is within a range of 0.25 to 1. The aforementioned range can be determined according to an operation voltage and process parameters of the ESD protection device 200, which is not limited by the invention. Moreover, the seventh doped region 230, the eighth doped region 232 and the ninth doped region 234 construct a fourth transistor T4. The fourth transistor T4 can also be a BJT, and a conductive type of the fourth transistor T4 is the same with the conductive type of the first transistor T1. Particularly, the eighth doped region 232, the first well 102 at the second side S2 of the second well 104 and the seventh doped region 230 may respectively serve as an emitter, a base and a collector of the BJT.

In some embodiments, the ESD protection device 200 may further include a second stack structure 236. The second stack structure 236 is located on the first well 102 between the seventh doped region 230 and the eighth doped region 232. The second stack structure 236 includes a second insulation layer 238 and a second conductive layer 240 sequentially stacked on the substrate 10. In some embodiments, the second stack structure 236, the seventh doped region 230 and the eighth doped region 232 may form a MOS transistor M2. Particularly, the second conductive layer 240 and the second insulation layer 238 of the second stack structure 236 may respectively serve as a gate and a gate dielectric layer of the MOS transistor M2. A material of the second conductive layer 240 may include polysilicon or a metal material. For example, the metal material may include tungsten or aluminum. A material of the second insulation layer 238 may include silicon oxide or other high dielectric constant material (for example, the dielectric constant is greater than 4). For example, the high dielectric constant material may include hafnium silicate, zirconium silicate, hafnium dioxide or zirconium dioxide. Moreover, the seventh doped region 230 and the eighth doped region 232 may serve as a drain/source of the MOS transistor M2.

Moreover, the ESD protection device 200 may further include a third isolation structure 242 and a fourth isolation structure 244. The third isolation structure 242 is located between the eighth doped region 232 and the ninth doped region 234, and the ninth doped region 234 is located between the third isolation structure 242 and the fourth isolation structure 244. For simplicity's sake, the first isolation structure 124 to the fourth isolation structure 244 are omitted in FIG. 3B. In some embodiments, the third isolation structure 242 and the fourth isolation structure 244 can be a field oxide layer (FOX) or a local oxidation of silicon (LOCOS) structure, and can be disposed on the substrate 10. In other embodiments, the third isolation structure 242 and the fourth isolation structure 244 can also be a shallow trench isolation (STI) structure, and is disposed in the substrate 10.

In some embodiments, the first doped region 106, the second doped region 108, the first conductive layer 116, the eighth doped region 232, the second conductive layer 240 and the ninth doped region 234 can be electrically connected to the cathode through the contacts 128. The third doped region 110, the fourth doped region 118, the fifth doped region 120, the sixth doped region 122 and the seventh doped region 230 can be electrically connected to the anode through the contacts 128. In this way, the first transistor T1 and the fourth transistor T4 can be connected in parallel, and the second transistor T2 and the third transistor T3 can be connected in parallel. In the present embodiment, the SCR in the ESD protection device 200 may include the first transistor T1 to the fourth transistor T4.

When the electronic device of the ESD protection device 200 receives the abnormal high voltage during the operation thereof, the SCR of the ESD protection device 200 is turned on to discharge the charges. In some embodiments, the first transistor T1 and the fourth transistor T4 can be first turned on, and then the second transistor T2 and the third transistor T3 are turned on. In other embodiments, the second transistor T2 and the third transistor T3 can also be first turned on, and then the first transistor T1 and the fourth transistor T4 are turned on.

The method for ESD of the present embodiment is similar to the method for ESD shown in FIG. 1C, and only differences therebetween are described below. In the step S102, the seventh doped region 230 is further electrically coupled to the third doped region 110 to the sixth doped region 122. In the step S104, the eighth doped region 232, the ninth doped region 234 and the second conductive layer 240 are electrically coupled to the first doped region 106, the second doped region 108 and the first conductive layer 116.

Then, in the step S106, the third doped region 110 to the seventh doped region 230 receive an electrostatic voltage. Moreover, in the step S108, the first doped region 106, the second doped region 108, the first conductive layer 116, the eighth doped region 232, the ninth doped region 234 and the second conductive layer 240 are connected to the ground electrode.

Then, in the step S110, the first transistor T1 and the second transistor T2 are respectively turned on. Particularly, while the sub step S110a is executed, the fourth transistor T4 is also turned on. Moreover, while the sub step S110b is executed, the third transistor T3 is also turned on. In this way, the first transistor T1 to the fourth transistor T4 may commonly discharge the electrostatic charges.

Similar to the third doped region 110 and the fourth doped region 118 shown in FIG. 1A and FIG. 1B, sectional conduction of the SCR of the ESD protection device 200 can be implemented through the sixth doped region 122 and the seventh doped region 230 of the present embodiment. Moreover, by controlling the MOS transistor M2 to maintain the cut off state, current leakage between the seventh doped region 230 and the eighth doped region 232 can be decreased. Moreover, by connecting the fourth transistor T4 and the first transistor T1 in parallel, the current discharge amount of the SCR is further increased, so as to further speed up discharge of the charges.

In summary, the third doped region and the fourth doped region with the same conductive type are contacted with each other, and cross over the first well and the second well of two complementary conductively types. In this way, the ESD protection device may sectionally turn on a plurality of transistors after receiving the abnormal high voltage, so as to discharge the charges. Therefore, the SCR of the ESD protection device may have the double snap-back characteristics. In other words, the SCR may have a lower trigger voltage, so as to decrease the damage on the electronic device electrically coupled to the ESD protection device caused by the abnormal high voltage. Moreover, the SCR also has a higher holding voltage, so as to avoid a situation that an operation voltage of the electronic device exceeds the holding voltage to trigger the latch-up effect.

It will be apparent to those skilled in the art that various modifications and variations can be made to the structure of the invention without departing from the scope or spirit of the invention. In view of the foregoing, it is intended that the invention cover modifications and variations of this invention provided they fall within the scope of the following claims and their equivalents.

What is claimed is:

1. An electrostatic discharge protection device, comprising:
a first well, located in a substrate, and having a first doped region, a second doped region and a third doped region to form a first transistor;
a second well, located in the substrate at one side of the first well;
a fourth doped region, located in the second well, and contacted with the third doped region, wherein a conductive type of the fourth doped region is the same with a conductive type of the third doped region;
a fifth doped region, located in the second well, wherein the fifth doped region, the second well and the substrate form a second transistor, and a conductive type of the second transistor is complementary to a conductive type of the first transistor; and
a sixth doped region, located in the second well, wherein the fifth doped region is located between the fourth doped region and the sixth doped region.

2. The electrostatic discharge protection device as claimed in claim 1, wherein the substrate, the first well, the first doped region and the fifth doped region have a first conductive type, and the second well, the second doped region, the third doped region, the fourth doped region and the sixth doped region have a second conductive type.

3. The electrostatic discharge protection device as claimed in claim 1, wherein the second doped region is located between the first doped region and the third doped region.

4. The electrostatic discharge protection device as claimed in claim 1, wherein a ratio between a width of the third doped region from one side opposite to the fourth doped region to another side contacting the fourth doped region and a width of the fourth doped region from one side contacting the third doped region to another side opposite to the third doped region is within a range of 1 to 4.

5. The electrostatic discharge protection device as claimed in claim 1, further comprising a first stack structure located on the first well between the second doped region and the third doped region and comprising a first insulation layer and a first conductive layer sequentially stacked on the substrate.

6. The electrostatic discharge protection device as claimed in claim 1, further comprising a first isolation structure and a second isolation structure, wherein the first isolation structure is located between the first doped region and the second doped region, and the first doped region is located between the first isolation structure and the second isolation structure.

7. The electrostatic discharge protection device as claimed in claim 5, wherein the first doped region, the second doped region and the first conductive layer are electrically connected to a cathode, and the third doped region, the fourth doped region, the fifth doped region and the sixth doped region are electrically connected to an anode.

8. The electrostatic discharge protection device as claimed in claim 1, wherein a top view pattern of the first well surrounds a top view pattern of the second well.

9. The electrostatic discharge protection device as claimed in claim 8, further comprising a seventh doped region, an eighth doped region and a ninth doped region, wherein the first doped region, the second doped region and the third doped region are located at a first side of the second well, and the seventh doped region, the eighth doped region and the ninth doped region are located at a second side of the second well, and the first side and the second side are opposite to each other, the seventh doped region, the eighth doped region and the ninth doped region form another transistor, and a conductive type thereof is the same with the conductive type of the first transistor.

10. The electrostatic discharge protection device as claimed in claim 9, wherein the ninth doped region has the first conductive type, and the seventh doped region and the eighth doped region have the second conductive type.

11. The electrostatic discharge protection device as claimed in claim 9, wherein a ratio between a width of the sixth doped region measured from one side opposite to the seventh doped region to another side contacting the seventh doped region and a width of the seventh doped region measured from one side contacting the sixth doped region to another side opposite to the sixth doped region is within a range of 1 to 4.

12. The electrostatic discharge protection device as claimed in claim 9, further comprising a third isolation structure and a fourth isolation structure, wherein the third isolation structure is located between the eighth doped region and the ninth doped region, and the ninth doped region is located between the third isolation structure and the fourth isolation structure.

13. The electrostatic discharge protection device as claimed in claim 9, further comprising:
a second stack structure, located on the first well between the seventh doped region and the eighth doped region, and comprising a second insulation layer and a second conductive layer sequentially stacked on the substrate.

14. The electrostatic discharge protection device as claimed in claim 13, wherein the third doped region, the fourth doped region, the fifth doped region, the sixth doped region and the seventh doped region are electrically connected to the anode, and the first doped region, the second doped region, the first conductive layer, the eighth doped region, the second conductive layer and the ninth doped region are electrically connected to the cathode.

15. A method for electrostatic discharge, comprising:
providing the electrostatic discharge protection device as claimed in claim 1;
electrically connecting the third doped region, the fourth doped region, the fifth doped region and the sixth doped region;
electrically connecting the first doped region and the second doped region;
receiving an electrostatic voltage by the third doped region, the fourth doped region, the fifth doped region and the sixth doped region;
connecting the first doped region and the second doped region to a ground electrode;
turning on the first transistor within a first time interval according to the electrostatic voltage; and
turning on the second transistor within a second time interval according to the electrostatic voltage, such that the first transistor and the second transistor discharge electrostatic charges.

16. The method for electrostatic discharge as claimed in claim 15, wherein a start point of the first time interval is different to a start point of the second time interval.

17. The method for electrostatic discharge as claimed in claim 16, wherein the start point of the first time interval is earlier than the start point of the second time interval.
